(19) United States
(12) Patent Application Publication
(10) Pub. No.: US 2023/0299109 A1
(43) Pub. Date: Sep. 21, 2023

(54) STACKED IMAGE SENSORS AND METHODS OF MANUFACTURING THEREOF

(71) Applicant: Taiwan Semiconductor Manufacturing Company, Ltd., Hsinchu (TW)

(72) Inventors: Chi-Hsien Chung, New Taipei City (TW); Tzu-Jui Wang, Fengshan City (TW); Chen-Jong Wang, Hsinchu City (TW); Tzu-Hsuan Hsu, Kaohsiung City (TW); Dun-Nian Yaung, Taipei City (TW); Calvin Yi-Ping Chao, Zhubei City (TW)

(73) Assignee: Taiwan Semiconductor Manufacturing Company, Ltd., Hsinchu (TW)

(21) Appl. No.: 17/850,734

(22) Filed: Jun. 27, 2022

Related U.S. Application Data
(60) Provisional application No. 63/321,486, filed on Mar. 18, 2022.

(51) Int. Cl. H01L 27/146; H01L 23/00

(52) U.S. Cl. CPC H01L 27/14634; H01L 27/14636; H01L 24/08; H01L 24/80; H01L 27/1469; H01L 2224/08145; H01L 2224/80895; H01L 2224/80896

(57) ABSTRACT

A semiconductor device includes a first chip comprising a plurality of photo-sensitive devices, wherein the plurality of photo-sensitive devices are formed as a first array. The semiconductor device includes a second chip bonded to the first chip and comprising: a plurality of groups of pixel transistors, wherein the plurality of groups of pixel transistors are formed as a second array; and a plurality of input/output transistors, wherein the plurality of input/output transistors are disposed outside the second array. The semiconductor device includes a third chip bonded to the second chip and comprising a plurality of logic transistors.

### CROSS-REFERENCE TO RELATED APPLICATION

This application claims priority to and the benefit of U.S. Provisional Application No. 63/321,486, filed Mar. 22, 2022, entitled “STACKED COMPLEMENTARY METAL-OXIDE-SEMICONDUCTOR IMAGE SENSORS,” which is incorporated herein by reference in its entirety for all purposes.

### BACKGROUND

As technologies evolve, complementary metal-oxide semiconductor (CMOS) image sensors are gaining in popularity over traditional charged-coupled devices (CCDs) due to certain advantages inherent in the CMOS image sensors. In particular, a CMOS image sensor may have a high image acquisition rate, a lower operating voltage, lower power consumption and higher noise immunity. In addition, CMOS image sensors may be fabricated on the same high volume wafer processing lines as logic and memory devices. As a result, a CMOS image chip may comprise both image sensors and all the necessary logics such as amplifiers, A/D converters and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of an example image sensor including a number of chips vertically integrated with each other, in accordance with some embodiments.

FIG. 2 is a circuit diagram of an example pixel unit of the image sensor of FIG. 1, in accordance with some embodiments.

FIGS. 3, 4, 5, 6, 7, 8, 9, 10, 11, and 12 illustrate cross-sectional views of the image sensor of FIG. 1 during various fabrication stages, in accordance with some embodiments.

FIG. 12 is a top view of an example image senor array of the image sensor of FIG. 1, in accordance with some embodiments.

FIG. 13 is a flow chart of an example method for fabricating an image sensor, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

CMOS image sensors are pixelated metal oxide semiconductors. A CMOS image sensor typically comprises an array of light sensitive picture elements (sometimes referred to as pixel units), each of which may include a number of transistors (e.g., a switching transistor and reset transistor), capacitors, and a photo-sensitive device (e.g., a photo diode). A CMOS image sensor utilizes light-sensitive CMOS circuitry to convert photons into electrons. The light-sensitive CMOS circuitry typically comprises a photo diode formed in a silicon substrate. As the photo diode is exposed to light, an electrical charge is induced in the photo diode. Each pixel may generate electrons proportional to the amount of light that falls on the pixel when light is incident on the pixel from a subject scene. Furthermore, the electrons are converted into a voltage signal in the pixel and further transformed into a digital signal through a number of logic circuits (e.g., an analog-to-digital converter (ADC) circuit, a digital-to-analog converter (DAC) circuit, etc.). A plurality of other logic circuits (e.g., a static random access memory (SRAM) circuit, a controller, a buffer storage, etc.) may receive the digital signals and process them to display an image of the subject scene.

A CMOS image sensor may comprise a plurality of additional layers such as dielectric layers and interconnect metal layers formed on top of the substrate, wherein the interconnect layers are used to couple the photo diode with peripheral circuitry. The side having additional layers of the CMOS image sensor is commonly referred to as a front side, while the side having the substrate is referred to as a backside. Depending on the light path difference, CMOS image sensors can be further divided into two major categories, namely front-side illuminated (FSI) image sensors and back-side illuminated (BSI) image sensors.

In a FSI image sensor, light from the subject scene is incident on the front side of the CMOS image sensor, passes through dielectric layers and interconnect layers, and finally falls on the photo diode. The additional layers (e.g., opaque and reflective metal layers) in the light path may limit the amount of light absorbed by the photo diode so as to reduce quantum efficiency. In contrast, there is no obstruction from additional layers (e.g., metal layers) in a BSI image sensor. Light is incident on the backside of the CMOS image sensor. As a result, light can strike the photo diode through a direct path. Such a direct path helps to improve photonic performance by increase the number of photons converted into electrons (i.e., higher efficiency in capturing photons).

To further improve the photonic performance of the BSI image sensor, the photo diodes of pixel units are typically formed over a relatively large area, which may force corresponding transistors of the pixel units to be formed over a relatively small area. Although the photonic performance may be improved, overall performance of the image sensor may be dragged by compromised electrical performance (due to the shrunk area to form the transistors of pixel units). This may lead to a proposal of separating the photo diodes and transistors of pixel units. For example, in some existing image sensors, the photo diodes, transistors of the pixel units, and the logic circuits may be formed on three respectively different chips, which are then (e.g., vertically) integrating with one another.

As technology nodes keep increasingly advancing forward, it may be desired to realize (e.g., integrate) more functions on the chip of the logic circuits by forming more advanced transistors on that chip. The present disclosure provides various embodiments of a vertically integrated backside illuminated (BSI) image sensor that allows such further improvement over the existing BIS image sensors. For example, the BIS image sensor, as disclosed herein, includes (i) a first chip including a number of photo-sensitive elements (e.g., respective photo diodes together with corresponding switching transistors of pixel units) formed as a first array; (ii) a second chip including a number of respective other transistors of the pixel units (sometimes referred to as pixel transistors) which are formed as a second array and a number of first logic circuits; and (iii) a third chip including a number of second logic circuits. The first array and second array may have a pixel-to-pixel mapping, while the first logic circuits may be formed around the second array to directly input and/or output electrical signals generated from the second array. Accordingly, the first logic circuits and the second logic circuits, which are formed on the different chips, can independently be manufactured and operated. For example, all of the second logic circuits can be made in more advanced technology nodes, when compared to the technology nodes to form the first logic circuits, which can significantly spare an amount of available area on the third chip. Further, the second logic circuits (which are mainly configured to process data generated from the first array and/or second array) can be operated under a relatively lower voltage, when compared to the voltage operating the first logic circuits (which are mainly configured to input/output the data generated from the second array). As such, various performance (e.g., power consumption, electrical/photonic speed, etc.) of the disclosed image sensor can be commensurately improved.

The present disclosure will be described with respect to embodiments in a specific context, a vertically integrated backside illuminated image sensor. The embodiments of the disclosure may also be applied, however, to a variety of image sensors and semiconductor devices. Hereinafter, various embodiments will be explained in detail with reference to the accompanying drawings.

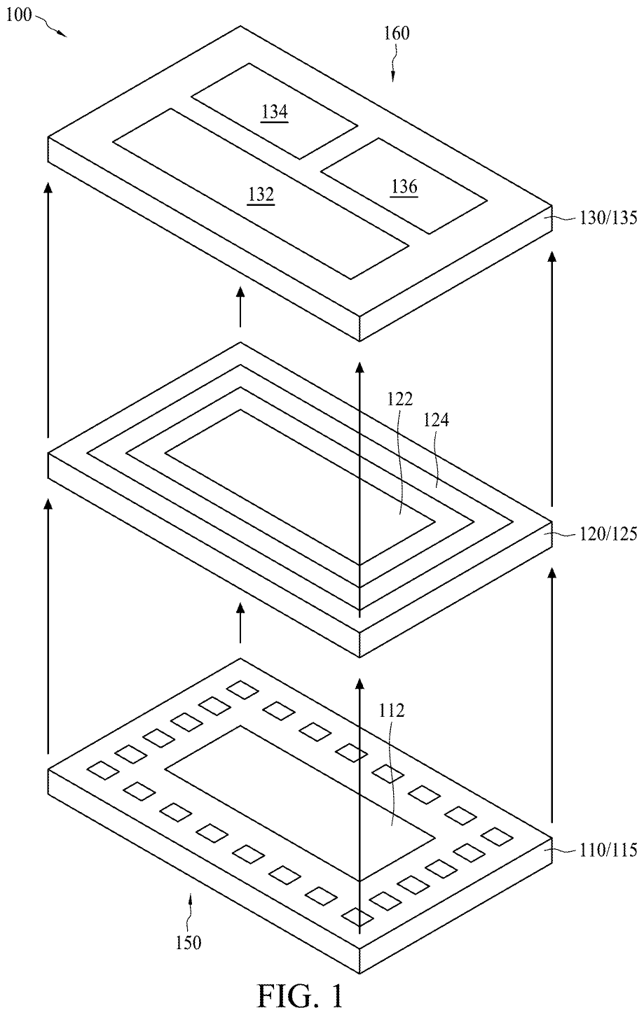

Referring to FIG. 1, depicted is an example schematic view of an image sensor 100 that includes three chips vertically integrated with one another, in accordance with various embodiments. For example, the image sensor 100 may be a backside illuminated (BSI) image sensor, with these chips stacked on top of one another. However, the staking scheme utilized by the BSI image sensor 100 may be applied to a frontside illuminated (FSI) image sensor, while remaining within the scope of the present disclosure.

As shown, a first chip 110 including an array 112 (with a number of photo-sensitive elements, e.g., photo diodes) is bonded to a second chip 120 including an array 122 (with a number of pixel transistors) together with a number of input/output circuits/components 124, for example, through metal-to-metal bonding or a hybrid bonding including both the metal-to-metal bonding and the oxide-to-oxide bonding. In some embodiments, each photo diode of the array 112, together with a corresponding group of pixel transistors of the array 122, may sometimes be referred to as a pixel unit. The second chip 120 is further bonded to a third chip 130, which may be an Application Specific Integrated Circuit (ASIC) chip. The third chip 130 may include Image Signal Processing (ISP) circuits 132, 134, and 136, and may, or may not, further include other circuits that are related to the BSI applications. The bonding of chips 110, 120, and 130 may be at wafer level. In such wafer-level bonding, wafers 115, 125, and 135, on which the chips 110, 120, and 130 are formed, respectively, are bonded together, and are then sawed into dies or the chips as shown. Alternatively, the bonding may be performed at a chip level.

When the image sensor 100 is implemented as a BSI image sensor, light may be received from a backside thereof. For example, the array 112 can receive light 150 emitted through a backside of the chip 110/wafer 115. When the image sensor 100 is implemented as an FSI image sensor, light may be received from a frontside thereof. For example, the array 112 can receive light 160 emitted through a frontside of the chip 130/wafer 135.

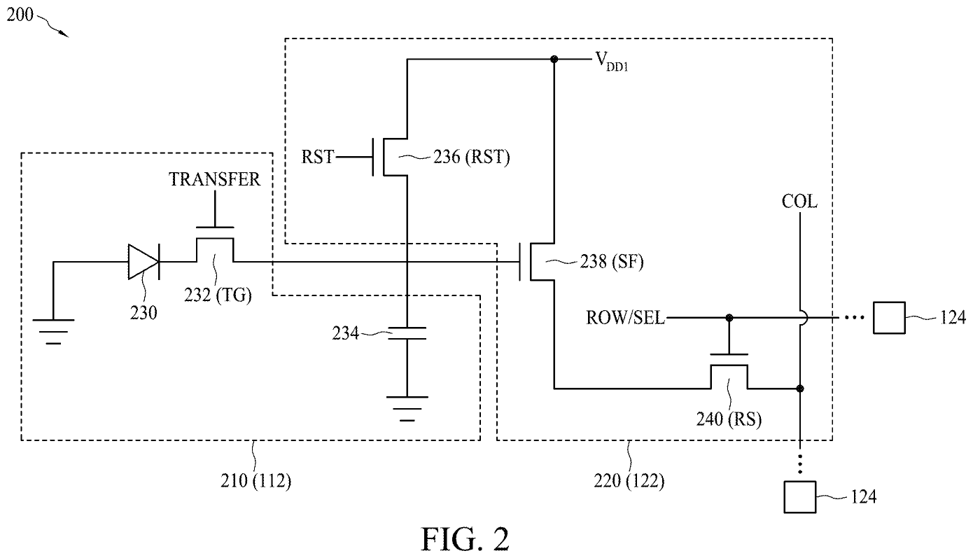

FIG. 2 illustrates an example circuit diagram of one of the disclosed pixel units, e.g., pixel unit 200, in accordance with various embodiments. As shown, the pixel unit 200 includes a first portion 210 formed in or on chip 110, and a second portion 220 formed in or on chip 100. In some embodiments, the first portion 210 includes a photo diode 230, a transfer gate (switching) transistor 232, and a floating diffusion capacitor 234; and the second portion 220 includes a reset transistor 236, a source follower 238, a row selector 240, which are sometimes collectively referred to as pixel transistors.

It should be appreciated that the circuit diagram of the pixel unit 200 shown in FIG. 2 is merely an example, and thus, each pixel unit can omit or include any of various other components while remaining within the scope of the present disclosure. For example, even though the pixel unit 200 is configured in four-transistor structure, the pixel unit 200 can be configured in various other structures, including but not limited to, a three-transistor structure, a five-transistor structure, or the like.

Specifically, the photo diode 230 has an anode coupled to the electrical ground, and a cathode coupled to a source of the transfer gate transistor 232, which has a gate coupled to a signal line. The signal line is marked as “TRANSFER” in FIG. 2, which is sometimes referred to as a transfer line. The transfer lines of the pixel units 200 may be connected to the ISP circuits 132-136 formed on the chip 130 (FIG. 1) and/or connected to the input/output circuits 124 formed on the chip 120 so as to receive control signals. A drain of the transfer gate transistor 232 may be coupled to a drain of the reset transistor 236 and a gate of the source follower 238. The reset transistor 236 has a gate coupled to a reset line RST, which may be connected to the ISP circuits 132-136 formed on the chip 130 (FIG. 1) to receive further control signals. A source of the reset transistor 236 may be coupled to a pixel power supply voltage VDD1 greater than 2 volts (V), e.g., 2.5V, 2.8V, 3.3V, etc., in accordance with various embodiments. The floating diffusion capacitor 234 may be coupled between the source/drain of transfer gate transistor 232 and the gate of source follower 238. The reset transistor 236 is used to preset the voltage at the floating diffusion capacitor 234 to VDD1. A drain of the source follower 238 is coupled to the same power supply voltage VDD1. A source of the source follower 238 is coupled to the row selector 240. The source follower 238 can provide a high-impedance output for the pixel unit 200. The row selector 240 may function as the select transistor of the respective pixel unit 200, and the gate of the row selector 240 is coupled to a select line SEL formed as one of a number of rows of the array 122. The select line/row may be electrically coupled to (e.g., controlled by) the input/output circuits 124 formed on the chip 120 (FIG. 1). A drain of the row selector 240 is coupled to an output line formed as one of a number of columns of the array 122. The output line/column may be electrically coupled to the input/output circuits 124 formed on the chip 120 to output the signal generated in the photo diode 230.

In the operation of pixel unit 200, when light is received by the photo diode 230, the photo diode 230 generates electrical charges, wherein the amount of the charges is related to the intensity or the brightness of the incident light. The electrical charges are transferred by enabling the transfer gate transistor 232 through a transfer signal applied to the gate of the transfer gate transistor 232. The electrical charges may be stored in the floating diffusion capacitor 234. The electrical charges enables the source follower 238, thereby allowing an electrical charges generated by the photo diode 230 to pass through the source follower 238 to the row selector 240. When sampling is desired, the select line SEL is enabled or the corresponding row is asserted (e.g., by one or more of the input/output circuits 124), allowing the electrical charges to conduct through the row selector 240 and the corresponding column (e.g., asserted by one or more of the input/output circuits 124) to the data process circuits, for example, the ISP circuits 132-136, which are coupled to the output of the row selector 240.

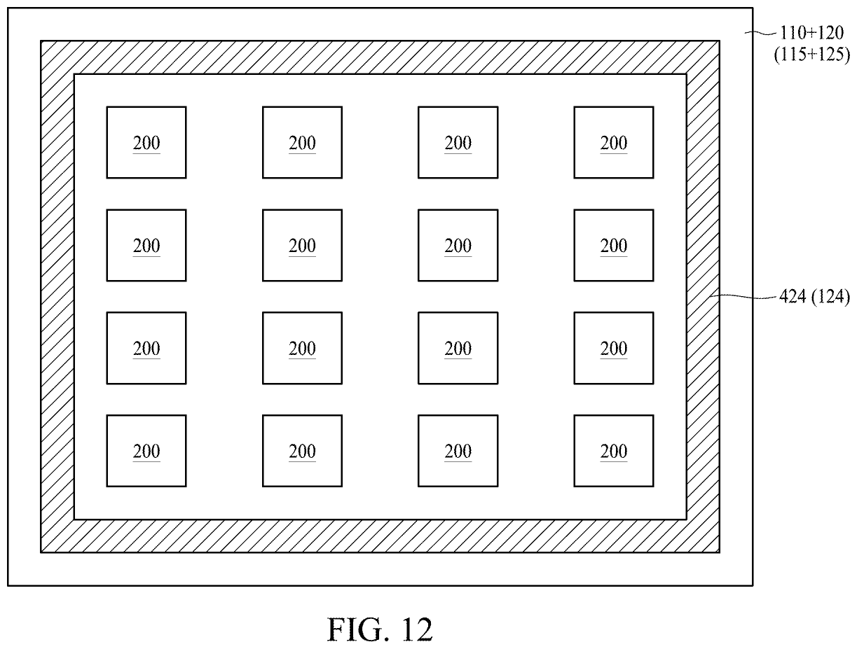

Referring again to FIG. 1, the array 112 of the chip 110 and the array 122 of the chip 120 may be bonded to each other at a pixel level. Each photo diode (e.g., 230) of the array 112 has a one-to-one physical and electrical correspondence to a respective group of pixel transistors (e.g., 236-240) of the array 122. In other words, the pixel units, formed from the components of different arrays 112 and 122, respectively, can equivalently form an image sensor array, as shown in FIG. 12. For example, when the chips 120 and 110 are bonded to each other, directly beneath/above each group of pixel transistors of the chip 120 is a corresponding one of the photo diodes of the chip 110. Such a corresponding pair of a group of pixel transistors and a photo diode can be electrically coupled to each other through one or more connector structures, in accordance with some embodiments. Further, around the array 122, the chip 120 includes a number of input/output transistors (collectively functioning as the input/output circuits 124) electrically connected to the pixel transistors of the array 122. The pixel transistors of the array 122 and the input/output transistors of the circuits 124 may sometimes be referred to as “in-array transistors 122” and “out-of-array transistors 124,” respectively.

Instead of being formed at the pixel level (like the in-array transistors 122), the out-of-array transistors 124 may be formed at a column level or row level. For example, the in-array transistors 122 may be formed as a number of columns and a number of rows intersecting with one another. Corresponding (e.g., operatively coupled) to each or a group of the columns of the in-array transistors 122 is a respective one or group of the out-of-array transistors 124. As such, each one or each group of the out-of-array transistors 124 can control (e.g., access, output, etc.) a corresponding column of the in-array transistors 122. In another example, corresponding (e.g., operatively coupled) to each or a group of the rows of the in-array transistors 122 is a respective one or group of the out-of-array transistors 124. As such, each one or each group of the out-of-array transistors 124 can control (e.g., access, output, etc.) a corresponding row of the in-array transistors 122. In various embodiments, the out-of-array transistors 124 can collectively function as at least one of the following circuits: an electrostatic discharge (ESD) protection circuit, a column control circuit (a column decoder), a row control circuit (a row decoder), or a level shift circuit.

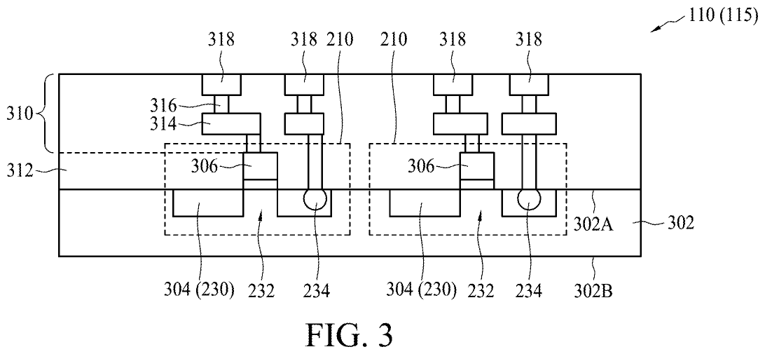

FIGS. 3 through 11 illustrate cross-sectional views of various intermediate stages to form the image sensor 100, in accordance with some example embodiments. The image sensor 100 shown in FIGS. 3-11 are simplified for illustration purpose, and thus, it should be understood that the image sensor device 100 can include any of various other components, while remaining within the scope of the present disclosure.

FIG. 3 illustrates an example cross-sectional view of the chip 110, which may be a part of the wafer 115 that includes a plurality of the chips 110 therein, in accordance with various embodiments. The chip 110 includes a semiconductor substrate 302, which may be a crystalline silicon substrate or a semiconductor substrate formed of other semiconductor materials. Throughout the description, surface 302A is referred to as a front surface of semiconductor substrate 302, and surface 302B is referred to as a back surface of semiconductor substrate 302. Image sensors 304 are formed at the front surface 302A of semiconductor substrate 302. The image sensors 302 are configured to convert light signals (photons) to electrical signals, and may be photo-sensitive Metal-Oxide-Semiconductor (MOS) transistors or photo-sensitive diodes. Accordingly, throughout the description, the image sensors 302 are interchangeably referred to as photo diodes 230, although they may be other types of image sensors. In some embodiments, photo diodes 230 each extend from the front surface 302A into semiconductor substrate 302, and collectively form an image sensor array, which is illustrated in a top view shown in FIG. 12.

In some embodiments, each of the photo diodes 230 is electrically coupled to the first source/drain region of a corresponding transfer gate transistor 232, which includes gate 306. The first source/drain region of the transfer gate transistor 232 may be shared by the connecting photo diode 230. The floating diffusion capacitor 234 is formed in the substrate 302, for example, through implanting into substrate to form a p-n junction, which acts as the floating diffusion capacitor 234. The floating diffusion capacitor 234 may be formed in a second source/drain region of transfer gate transistor 232, and hence one of the capacitor plates of the floating diffusion capacitor 234 is electrically coupled to the second source/drain region of the transfer gate transistor 232. The photo diode 230, transfer gate transistor 232, and floating diffusion capacitor 234 form the portion 210 of each pixel unit 200 (as shown in FIG. 2).

In some embodiments, the chip 110 and the wafer 115 (where the chip is formed) are free from, or substantially free from, additional logic devices (for example, logic transistors) other than the transfer gate transistors 232. Furthermore, the chip 110 and wafer 115 may be free from the peripheral circuits of image sensor chips, which peripheral circuits include, for example, the Image Signal Processing (ISP) circuits, which may include Analog-to-Digital Converters (ADCs), Correlated Double Sampling (CDS) circuits, row decoders, column decoders, or the like.

Referring still to FIG. 3, a number of front-side interconnect structure 310 are formed over the semiconductor substrate 302, and are used to electrically interconnect the devices in the chip 110. The front-side interconnect structures 310 include one or more dielectric layers 312 embedding a respective number of metal lines 314 and vias 316 therein. Throughout the description, the metal lines 314 in a same dielectric layer 312 are collectively referred to as being a metal or metallization layer. The interconnect structures 310 may include a plurality of metal layers. The dielectric layers 312 may include low-k dielectric layers and possibly a passivation layer(s) over the low-k dielectric layers. The low-k dielectric layers have low k (dielectric constant) values, for example, lower than about 3.0. The passivation layer may be formed of a non-low-k dielectric material having a k value greater than 3.9.

At the front surface of the substrate 302 are metal pads 318, which may have a high surface flatness achieved by a planarization step such as Chemical Mechanical Polish (CMP). The top surfaces of the metal pads 318 are substantially level with the top surface of a topmost one of the dielectric layers 312, and are substantially free from dishing and erosion. The metal pads 318 may comprise copper, aluminum, and possibly other metals. In some embodiments, each of the gates 306 of the transfer gate transistors 232 can be electrically coupled to one of the metal pads 318. Accordingly, the gates 306 can receive transfer signals through the metal pads 318 from, e.g., the ISP circuits 132-136 in the chip 130 (FIG. 1). Each of the floating diffusion capacitor 234 is electrically coupled to one of the metal pads 318, so that the charges stored in the diffusion capacitor 234 may be discharged to one or more of the pixel transistors, e.g., the source follower 238 (FIG. 2) through the respective coupling metal pads 318. Accordingly, each of the portions 210 (FIG. 2) may include at least two of the metal pads 318. It is appreciated that the number of the metal pads 318 in each of the portions 210 is related to the configuration of the corresponding pixel units 200. Accordingly, each of the portions 210 may include a different number of the metal pads such as, for example, 3, 4, 5, etc., while remaining within the scope of the present disclosure.

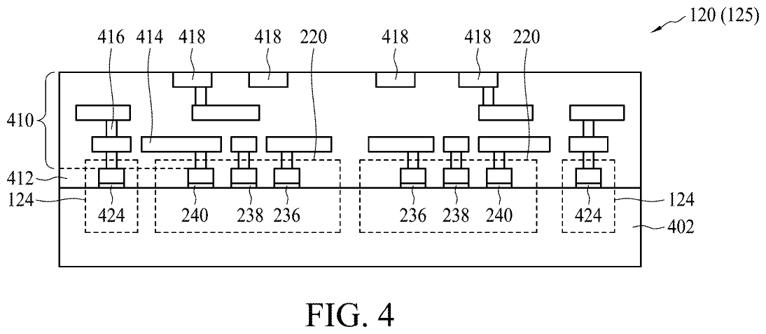

FIG. 4 illustrates an example cross-sectional view of the chip 120, which is in the wafer 125 that comprises a plurality of identical device chips identical to the chip 120, in accordance with various embodiments. The chip 120 includes a semiconductor substrate 402, which may be a crystalline silicon substrate or a semiconductor substrate formed of other semiconductor materials. The substrate 402 is a silicon substrate in some embodiments. Alternatively, the substrate 402 is formed of other semiconductor materials such as silicon germanium, silicon carbon, III-V compound semiconductor materials, or the like. The chip 120 further includes a number of pixel transistors formed at a front surface of the substrate 402, which form the portions 220 of the pixel unit 200 (as shown in FIG. 2). As shown in FIG. 4, the chip 120 includes a plurality of transistors, including the row selectors 240, source followers 238, and reset transistors 236. The row selectors 240, source followers 238, and reset transistors 236 may form the portions 220 of a plurality of pixel units 200, with each of portions 220 including one of the row selectors 240, one of the source followers 238, and one of the reset transistors 236.

In various embodiments, the chip 120 further includes a number of input/output transistors 424, collectively forming the input/output circuits 124. As mentioned above, the pixel transistors 236 to 240 may be referred to as the in-array transistors, and the input/output transistors 424 may be referred to as the out-of-array transistors, in which the pixel transistors 236 to 240 (forming the portion 220 of one pixel unit 200) may one-to-one correspond to the photo diode 230, transfer gate transistor 232, and capacitor 234 (forming the portion 210 of the pixel unit 200). As such, the input/output transistors 424 may not form an array. Instead, the out-of-array transistors 424 may be formed along edges or sides of the array constituted by the in-array transistors 236-240.

A number of interconnect structures 410 are formed over the portions 220, and are configured to electrically couple the portions 220 to the input/output circuits 124 in chip 120 and/or the ISP circuits 132-136 in the chip 130 (FIG. 1). The interconnect structure 410 include a plurality of metal layers in a plurality of dielectric layers 412. Metal lines 414 and vias 416 are disposed in the dielectric layers 412. For example, a gate of the row selector 240 can be electrically coupled to the source or drain of one of the input/output transistors 424 through one or more of the metal lines 414 and vias 416, while a source of the row selector 240 can be electrically coupled to the source or drain of another one of the input/output transistors 424 through one or more of the metal lines 414 and vias 416. In some embodiments, the dielectric layers 412 include low-k dielectric layers. The low-k dielectric layers may have low k (dielectric constant) values that are lower than about 3.0. The dielectric layers 412 may further include a passivation layer formed of non-low-k dielectric materials having k values greater than 3.9. In some embodiments, the passivation layer includes a silicon oxide layer, an un-doped silicate glass layer, and/or the like.

Metal pads 418 are formed at the surface of wafer 125, wherein the metal pads 418 may have high surface flatness achieved by CMP with substantially low dishing or erosion effect with relative to the top surface of the topmost dielectric layer 412. The metal pads 418 may also comprise copper, aluminum, and/or other metals. In some embodiments, a gate of each of the source followers 238 can be electrically coupled to one of the metal pads 418. Accordingly, the source followers 238 can be enabled by the floating diffusion capacitors 234 in chip 110, so as to allow the electrical charges generated by the photo diodes 230 also in chip 110 to pass through the source follower 238 to the row selector 240. Accordingly, each of the portions 220 is electrically connected to at least one of the metal pads 418.

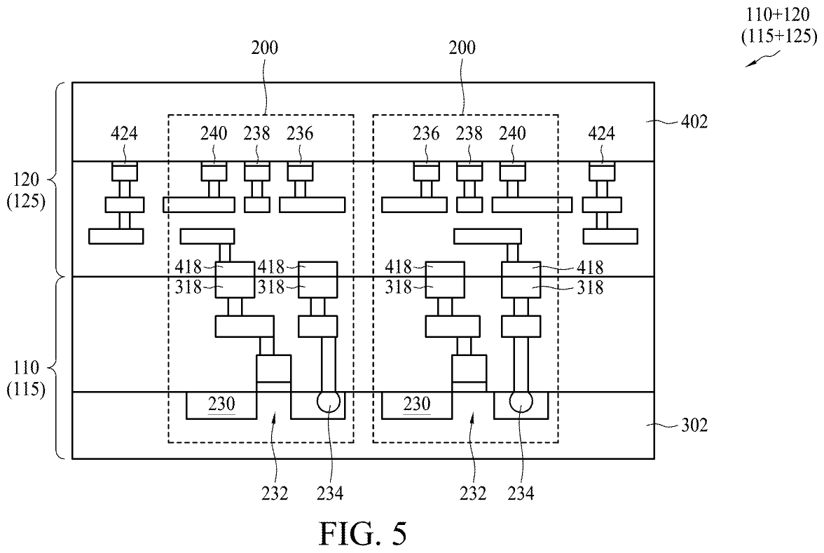

Referring to FIG. 5, illustrated is an example cross-sectional view of the image sensor 100 in which the chip 110 (the wafer 115) and the chip 120 (the wafer 125) are bonded to each other through the bonding of metal pads 318 to the respective metal pads 418, in accordance with various embodiments. The bonding may be a bonding with no extra pressure applied, and may be performed at room temperature (for example, around 21° C.). The top oxide layer (not shown) of chip 110 is bonded to the top oxide layer (not shown) of chip 120 through oxide-to-oxide bonding when metal pads 42 are bonded to metal pads 142. As a result of the bonding, the photo diodes 230, transfer gate transistors 232, floating diffusion capacitors 234, row selectors 240, source followers 238, and reset transistors 236 are coupled to form a number of the pixel units 200. In some embodiments, the pixel units 200 can form an image sensor array corresponding to the array of photo diodes 230, as shown in FIG. 12. Accordingly, the corresponding metal pads 318 and 418 may also be arranged as an array. As further shown in FIG. 12, the input/output transistors 424 (collectively functioning as the input/output circuits 124) can be arranged around such an image sensor array of the pixel units 200.

In the illustrated example of FIG. 5, the chips 110 and 120 are bonded in a face-to-face (F2F) manner, i.e., the front surface of the chip 110 facing the front surface of the chip 120. When bonding in such a F2F manner, respective metal pads of the chips 110 and 120 may be utilized to electrically couple their respective components (e.g., coupling the first portion 210 of each pixel unit 200 to its second portion 220). However, it should be understood that the chips 110 and 120 can be boned in other manner, while remaining within the scope of the present disclosure. For example, the chips 110 and 120 may be bonded to each other in a face-to-back (F2B) manner, i.e., the front surface of the chip 110 facing the back surface of the chip 120.

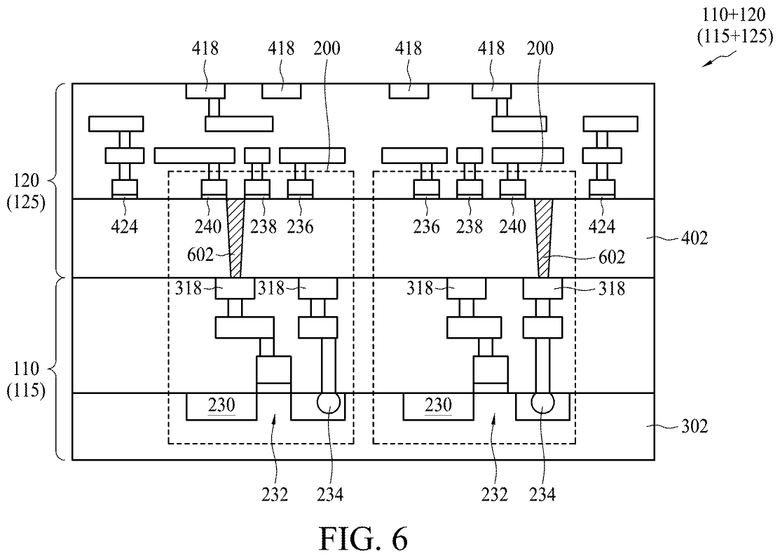

FIG. 6 illustrates an example cross-sectional view of the image sensor 100 in which the chip 110 and chip 120 are bonded to each other in a F2B manner, in accordance with various embodiments. As shown, the front surface of the substrate 302 where the chip 110 is formed faces the back surface of the substrate 402 where the chip 120 is formed. Although not shown, an oxide layer may be optionally formed between the chips 110 and 120. To electrically couple the chip 110 to the chip 120, the chip 120 may further include a number of through silicon/substrate via (TSV) structures 602 extending through the substrate 402. Specifically, each of the TSV structures 602 may be in electrical contact with a corresponding one of the meal pads 318 of the chip 110. For example, the floating diffusion capacitor 234 (of the chip 110) can be electrically coupled to the reset transistor 236 and source follower 238 (of the chip 120) through one or more interconnect structures (e.g., 310 of FIG. 3) of the chip 110, at least one of the metal pads 318, and at least one of the TSV structures 602, thereby forming a corresponding one of the pixel units 200 (as shown in FIG. 6).

For the purposes of clarity, the following fabrication stages of forming the image sensor 100 will be based on the chips 110 and 120 being bonded to each other in a F2F manner. It should be appreciated that those fabrication stages can also be used to form a complete image sensor 100 with the chips 110 and 120 being bonded to each other in a F2B manner, while remaining within the scope of the present disclosure. For example, another chip (e.g., the chip 130) can be bonded to the chip 120 using the metal pads 418, with that chip's metal pad (in a F2F manner) or TSV structures (in a F2B manner).

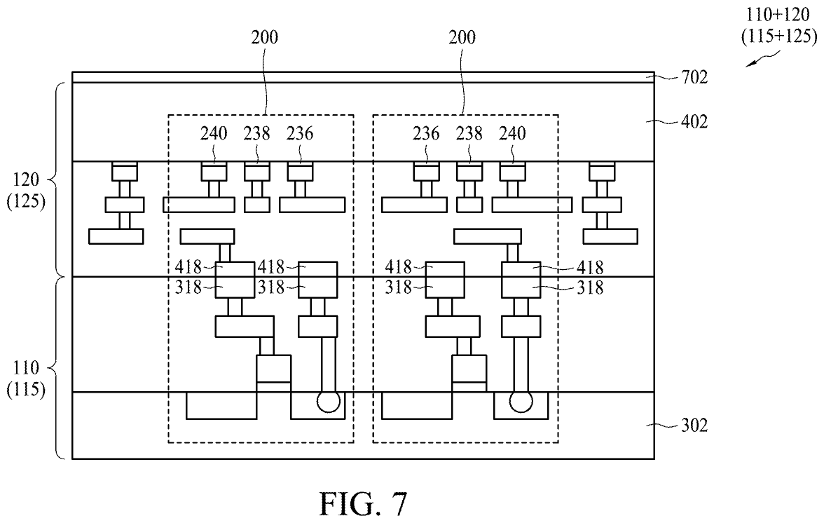

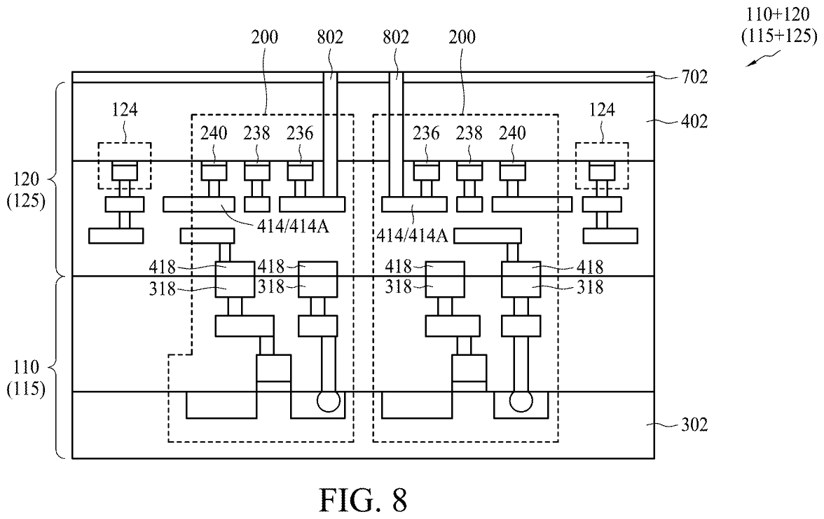

Referring to FIG. 7, illustrated is an example cross-sectional view of the image sensor 100 in which an oxide layer 702 is formed over the back surface of the substrate 402, in accordance with various embodiments. For the process of forming TSV structures 802 as shown in FIG. 8, a process of thinning down the substrate 402 to an optimized thickness may be performed before the formation of oxide layer 702. In some embodiments, the formation of oxide layer 702 is formed through the oxidation of the substrate 402. In alternative embodiments, the oxide layer 702 is deposited on the back surface of the substrate 402. The oxide layer 702 may comprise silicon oxide, for example.

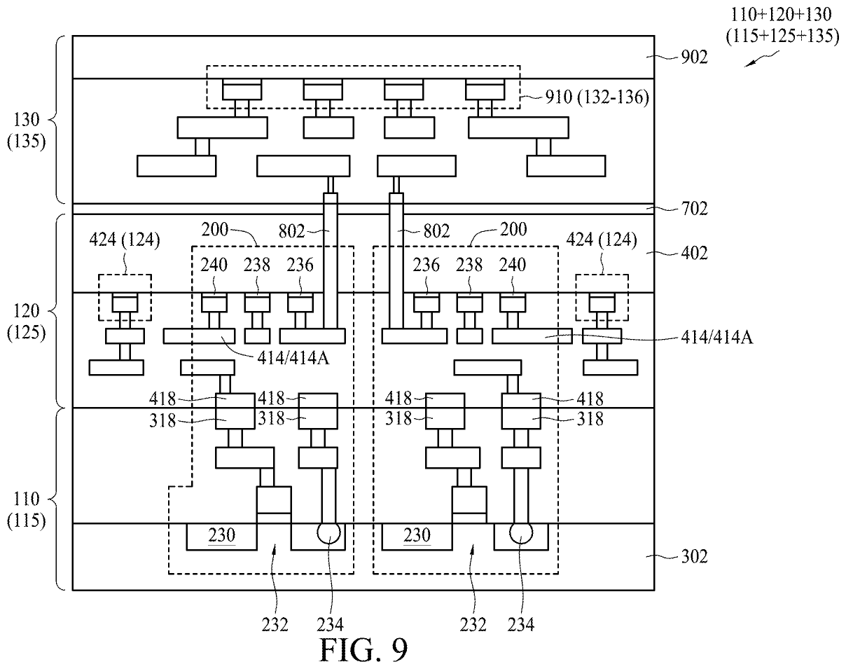

Next, in FIG. 8, illustrated is an example cross-sectional view of the image sensor 100 in which a number of TSV structures 802 are formed, in accordance with various embodiments. The formation process may include etching the oxide layer 702, the substrate 402, and one or more other dielectric layers formed in the chip 120 to form a TSV opening, until metal lines (or metal pads) 414A are exposed. Metal pads 414A may be disposed in the bottom metal layer that is closest to the devices 236 to 240, or may be disposed in a metal layer that is further away from devices 236 to 240 than the bottom metal layer. The TSV openings are then filled with a conductive material such as a metal or metal alloy, followed by a Chemical Mechanical Polish (CMP) to remove excess portions of the conductive material. As a result of the CMP, the top surfaces of TSV structures 802 may be substantially level with the top surface of oxide layer 702, which enables the bonding of the chip 120 to the chip 130, as shown in FIG. 9. For example, one of the TSV structures 802 (as shown in FIG. 8) can electrically couple the gate of the reset transistor 236 to one or more logic circuits of the chip 130. In another example, another of the TSV structures 802 (not shown) can electrically couple the source and the gate of the row selector 240 to one or more respective logic circuits of the chip 130.

Referring to FIG. 9, illustrated is an example cross-sectional view of the image sensor 100 in which the wafer 125 (including the chip 120) is bonded to the wafer 135 including a number of chips 130 therein, in accordance with various embodiments. The wafer 135 includes a semiconductor substrate 902, and logic transistors 910 formed adjacent to a front surface of semiconductor substrate 902. In some embodiments, the logic transistors 910 include one or more of ISP circuits (e.g., 132 to 136 of FIG. 1) that are used for processing the image-related signals obtained from chips 110 and 120. Example ISP circuits include ADC circuits, DAC circuits, CDS circuits, SRAM circuits, controllers, buffer storages, and/or the like. The logic transistors 910 may also function as an application specific circuit that is customized for certain applications. Through such a design, if the resulting package including stacked chips 110 to 130 is to be redesigned for a different application, the chip 130 may be redesigned, while the design of chips 110 and 120 does not need to be changed.

In some embodiments, the devices of the chip 110 (e.g., 230, 232, 234) and the devices of the chip 120 (e.g., 236, 238, 240, 424) may be operated under a first power supply voltage (e.g., VDD1), while the devices of the chip 130 (e.g., 910) may be operated under a second power supply voltage (e.g., VDD2) different from the first supply voltage. As a non-limiting example, VDD1 may be greater than 2V (e.g., 2.5V, 2.8V, 3.3V, etc.), and VDD2 may be less than 2V (e.g., 1.8V). As such, the devices of the chip 110 (e.g., 230, 232, 234) and the devices of the chip 120 (e.g., 236, 238, 240, 424) may be formed with a relatively thinner gate dielectric, and the devices of the chip 130 (e.g., 910) may be formed with a relatively thicker gate dielectric, in some embodiments.

Further, with the devices formed on the respective wafers (e.g., devices 230-234 on the wafer 115, devices 236-238 and 424 formed on the wafer 125, and devices 910 formed on the wafer 135), the devices can be fabricated with different technology nodes. For example, devices 230-234, 236-238, and 424, on the wafers 115 and 125, can be formed with a relatively mature (e.g., bigger) technology node, while devices 910, on the wafer 135, can be formed with a relatively advanced (e.g., smaller) technology node. In another example, devices 230-234, on the wafer 115, can be formed with a relatively mature (e.g., bigger) technology node, while devices 236-238, 424, and 910, on the wafers 125 and 135, can be formed with a relatively advanced (e.g., smaller) technology node. As a non-limiting example, a bigger technology node may sometimes be referred to as a longer channel or gate length. Similarly, a smaller technology node may sometimes be referred to as a shorter channel or gate length.

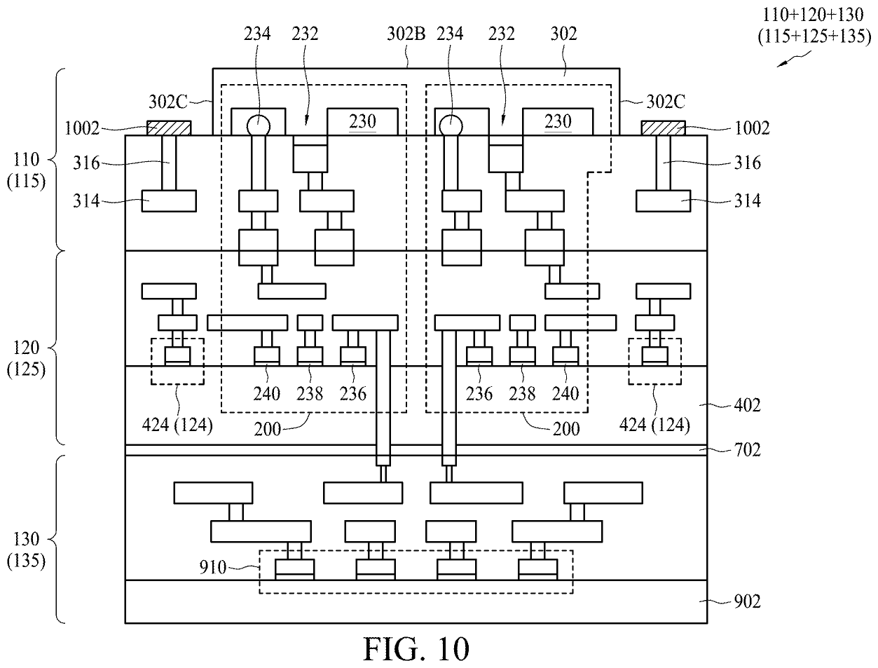

Next, in FIG. 10, illustrated is an example cross-sectional view of the image sensor 100 in which a backside grinding is performed to thin down the semiconductor substrate 302, and a thickness of the substrate 302 is reduced to a desirable value, in accordance with various embodiments. With the semiconductor substrate 302 having a small thickness, light may penetrate from the back surface 302B into the semiconductor substrate 302, and reach the image sensors 230. In the thin down process, the wafers 125 and 135 may collectively act as a carrier that provides mechanical support to the wafer 115, and may prevent the wafer 115 from breaking even though the wafer 115 has a relatively thin thickness during and after the thinning process. Accordingly, during the backside grinding, an additional carrier may not be needed.

FIG. 10 further illustrates the etching of substrate 302, and the formation of electrical connectors 1002. The electrical connectors 1002 may be bond pads, for example, the wire bond pads that are used for forming wire bonding. Through the electrical connectors 1002, the respective chips 110, 120, and 130 may be electrically coupled to external circuit components (not shown).

As shown in FIG. 10, the electrical connectors 1002 may be formed at a same level as the substrate 302. In some example formation process, the substrate 302 is first etched. For example, the edge portions of substrate 302 are etched, and a center portion of substrate 302, in which the image sensors 230 are formed, is not etched. As a result, some of the metal lines 314 and vias 316 may extend beyond edges 30C of substrate 302, as shown. In an example formation process, after the removal of the portions of substrate 302, an underlying dielectric layer is exposed. In some embodiments, the exposed dielectric layer is an Inter-Layer Dielectric (ILD), a Contact Etch Stop Layer (CESL), or the like. Next, a relatively deep via 316 is formed in the dielectric layers in the chip 110, and electrically couple to one or more metal lines 314. The formation process includes etching the dielectric layers to form openings, and filling the resulting openings with a conductive material to form the deep via 316. The electrical connectors 1002 are then formed, for example, by a deposition step followed by a patterning step.

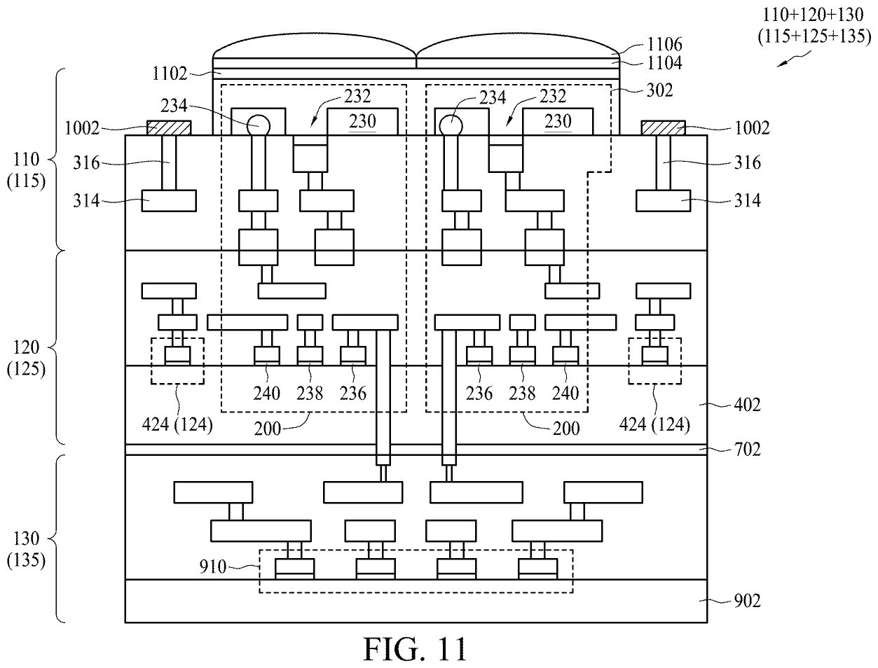

Next, in FIG. 11, illustrated is an example cross-sectional view of the image sensor 100 in which an upper layer 1102 (sometimes referred to as a buffer layer) is formed on the back surface of semiconductor substrate 302, in accordance with various embodiments. In some example embodiments, the upper layer 1102 includes one or more of a Bottom Anti-Reflective Coating (BARC), a silicon oxide layer, and a silicon nitride layer. In subsequent process steps, additional components such as metal grids (not shown), color filters 1104, micro-lenses 1104, and the like, are further formed on the backside of the wafer 115. The resulting stacked wafers 115, 125, and 135 are then sawed apart into dies, wherein each of the dies includes one chip 110, one chip 120, and one chip 130.

In accordance with various embodiments of the present disclosure, by moving at least some of, or possibly all of, the row selectors 240, source followers 238, and reset transistors 236 out of the chip 110, the fill factor of pixel units 200 is improved, wherein the fill factor may be calculated as the chip area occupied by the photo diode 230 divided by the total chip area of the respective pixel unit 200. The improvement in the fill factor results in the increase in the quantum efficiency of the pixels. Furthermore, by moving some of the logic circuits, e.g., input/output transistors 424 (collectively functioning as the input/output circuits 124), from the chip 130 to the chip 120, formation of some of the high-performance logic circuits (e.g., ADC circuits, DAC circuits, etc.) and formation of those input/output circuits can be decoupled. As such, the high-performance logic circuits and input/output circuits can be formed with independent technology nodes, which can significantly save fabrication cost and minimize any adverse effect induced from one to the other.

FIG. 12 illustrates a top view of an example image sensor array 1200 including a number of pixel units (e.g., 200), in accordance with various embodiments. As shown, when bonding at least the chip 110 (wafer 115) and chip 120 (wafer 125) to each other, the image sensor array 1200 that includes an array of a number (e.g., 16) of pixel units 200 is formed. Although 16 pixel units are shown in the image sensor array 1200, it should be understood that the image sensor array 1200 can include any number of pixel units while remaining within the scope of the present disclosure. Each pixel unit 200 includes at least a photo diode (e.g., 230), a floating diffusion capacitor (e.g., 234), and number of transistors (e.g., 232 to 240). The image sensor array 1200 may be formed by integration of the array 112 and the array 122 (FIG. 1), in accordance with some embodiments. Further, enclosing the image sensor array 1200, a number of input/output transistors (e.g., 424) that collectively function as the input/output circuit 124 (FIG. 1) are formed, in accordance with various embodiments.

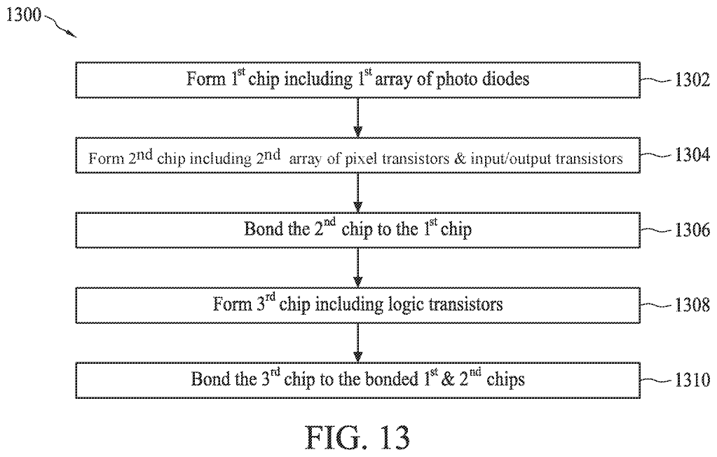

FIG. 13 illustrates a flow chart of an example method 1300 for forming an image sensor having a number of vertically integrated chips, in accordance with various embodiments of the present disclosure. It should be noted that the method 1300 is merely an example, and is not intended to limit the present disclosure. Accordingly, it is understood that the order of operation of the method 1300 of FIG. 13 can change, that additional operations may be provided before, during, and after the method 1300 of FIG. 13, and that some other operations may only be described briefly herein. Such an image sensor, made by the method 1300, may include one or more components, as discussed above with respect to FIGS. 1-12. Accordingly, operations of the method 1300 will sometimes be discussed in conjunction with FIGS. 1-12, as illustrative examples.

The method 1300 starts with operation 1302 of forming a first chip including a number of photo diodes formed as a first array, in accordance with some embodiments. For example, over a first wafer (e.g., 115), a number of first chips (e.g., 110), each of which includes a first array (e.g., 112) that includes a number of photo diodes (e.g., 230), can be formed. Further, corresponding to each photo diode of the first array, a transfer gate transistor (e.g., 232) and a floating diffusion capacitor (e.g., 234) are formed. Alternatively stated, each first chip over the first wafer includes at least a first array that is constituted by a number of photo diodes and a number of corresponding transfer gate transistors and floating diffusion capacitor.

The method 1300 continues to operation 1304 of forming a second chip including a number of pixel transistors formed as a second array and a number of input/output transistors formed outside the second array, in accordance with some embodiments. For example, over a second wafer (e.g., 125), a number of second chips (e.g., 120), each of which includes a second array (e.g., 122) that includes a number of pixel transistors (e.g., 236-240), can be formed. Further, around the second array, a number of input/output transistors (e.g., 424) can be formed. The input/output transistors (sometimes referred to as out-of-array transistors with respect to in-array transistors of the pixel transistors) can collectively function as one or more input/output circuits (e.g., an electrostatic discharge (ESD) protection circuit, a column control circuit (a column decoder), a row control circuit (a row decoder), a level shift circuit) of the image sensor, in some embodiments.

The method 1300 continues to operation 1306 of bonding the first chip to the second chip, in accordance with some embodiments. For example, the first chip 110 can be bonded to the second chip 120 through metal-to-metal bonding or a hybrid bonding including both the metal-to-metal bonding and the oxide-to-oxide bonding. However, it should be understood that the first and second chip can be bonded to each other in any of various other bonding techniques. In some embodiments, the first chip may be bonded to the second chip at a pixel level. Specifically, each element (e.g., a photo diode and its corresponding transfer gate transistor and floating diffusion capacitor) of the first array on the first chip 110 can physically and electrically correspond to a corresponding element (e.g., a number of pixel transistors) of the second array on the second chip 120. Further, the first chip can be bonded to the second chip in a F2F manner (with a front surface of the first chip facing a front surface of the second chip), or in a F2B manner (with a front surface of the first chip facing a back surface of the second chip).

The method 1300 continues to operation 1308 of forming a third chip including a number of transistors collectively functioning as a number of Image Signal Processing (ISP) circuits, in accordance with some embodiments. For example, over a third wafer (e.g., 135), a number of third chips (e.g., 130), each of which includes a number of ISP circuits (e.g., 132 to 136), can be formed. Example ISP circuits include, but are not limited to, ADC circuits, DAC circuits, CDS circuits, SRAM circuits, controllers, buffer storages, etc.

The method 1300 continues to operation 1310 of bonding the third chip to the already bonded first and second chips, in accordance with some embodiments. For example, following the bonding of the first and second chips, the third chip is bonded to the already bonded first and second chips. The third chip can be bonded to the second chip through metal-to-metal bonding or a hybrid bonding including both the metal-to-metal bonding and the oxide-to-oxide bonding. However, it should be understood that the third and second chip can be bonded to each other in any of various other bonding techniques. In some embodiments, the first to third chips may be bonded to each other through bonding the first wafer to the second wafer and to the third wafer, followed by dicing the bonded first to third wafers.

In one aspect of the present disclosure, a semiconductor device is disclosed. The semiconductor device includes a first chip comprising a plurality of photo-sensitive devices, wherein the plurality of photo-sensitive devices are formed as a first array. The semiconductor device includes a second chip bonded to the first chip and comprising: a plurality of groups of pixel transistors, wherein the plurality of groups of pixel transistors are formed as a second array; and a plurality of input/output transistors, wherein the plurality of input/output transistors are disposed outside the second array. The semiconductor device includes a third chip bonded to the second chip and comprising a plurality of logic transistors.

In another aspect of the present disclosure, a semiconductor device is disclosed. The semiconductor device includes a first chip, a second chip, and a third chip. The first chip comprises a first semiconductor substrate; a plurality of photo-sensitive devices formed over the first semiconductor substrate; a plurality of transfer gate transistors formed over the first semiconductor substrate; and a plurality capacitors formed over the first semiconductor substrate. The second chip comprises a second semiconductor substrate; a plurality of reset transistors formed over the second semiconductor substrate; a plurality of source followers formed over the second semiconductor substrate; a plurality of row selectors formed over the second semiconductor substrate; and a plurality of input/output transistors formed over the second semiconductor substrate. The third chip comprises a third semiconductor substrate; and a plurality of logic transistors formed over the third semiconductor substrate. The first to third chips are vertically boned to one another.

In yet another aspect of the present disclosure, a method for fabricating semiconductor devices is disclosed. The method includes forming a first chip including a plurality of photo-sensitive devices disposed over a first semiconductor substrate. The method includes forming a second chip including: (i) a plurality of reset transistors disposed over a second semiconductor substrate; (ii) a plurality of source followers disposed over the second semiconductor substrate; (iii) a plurality of row selectors disposed over the second semiconductor substrate; and (iv) a plurality of input/output transistors disposed over the second semiconductor substrate. The method includes bonding the second chip to the first chip. The method includes forming a third chip including a plurality of logic transistors disposed a third semiconductor substrate. The method includes bonding the third chip to the second chip.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first chip comprising a plurality of photo-sensitive devices, wherein the plurality of photo-sensitive devices are formed as a first array;
a second chip bonded to the first chip and comprising:
a plurality of groups of pixel transistors, wherein the plurality of groups of pixel transistors are formed as a second array; and
a plurality of input/output transistors, wherein the plurality of input/output transistors are disposed outside the second array; and
a third chip bonded to the second chip and comprising a plurality of logic transistors.

2. The semiconductor device of claim 1, wherein each of the photo-sensitive devices of the first array physically and electrically corresponds to a corresponding one of the groups of pixel transistors of the second array.

3. The semiconductor device of claim 1, wherein the input/output transistors collectively function as an input/output circuit for an image sensor constituted by the first to third chips.

4. The semiconductor device of claim 3, wherein the input/output circuit is selected from the group consisting of: an electrostatic discharge (ESD) protection circuit, a column decoder, a row decoder, a level shift circuit, and combinations thereof.

5. The semiconductor device of claim 1, wherein each of the photo-sensitive devices and a corresponding one of the groups of pixel transistors form at least, in part, one of a plurality of pixel units of an image sensor array.

6. The semiconductor device of claim 5, wherein each of the pixel units further includes a transfer gate transistor and a capacitor formed within the first array.

7. The semiconductor device of claim 1, wherein each of the groups of pixel transistor includes a reset transistor, a source follower, and a row selector.

8. The semiconductor device of claim 1, wherein the logic transistors collectively function as an Image Signal Processing (ISP) circuit selected from the group consisting of: an Analog-to-Digital Converter (ADC) circuit, a Digital-to-Analog Converter (DAC) circuit, a Correlated Double Sampling (CDS) circuit, and combinations thereof.

9. The semiconductor device of claim 1, wherein the plurality of groups of pixel transistors and the plurality of input/output transistors operate under a first supply voltage, and the plurality of logic transistors operate under a second supply voltage, and wherein the first supply voltage is substantially higher than the second supply voltage.

10. The semiconductor device of claim 1, wherein the plurality of groups of pixel transistors and the plurality of input/output transistors are formed with a first dimension, and the plurality of logic transistors are formed with a second dimension, and wherein the first dimension is substantially greater than the second dimension.

11. A semiconductor device, comprising:
a first chip comprising:
a first semiconductor substrate;
a plurality of photo-sensitive devices formed over the first semiconductor substrate;
a plurality of transfer gate transistors formed over the first semiconductor substrate; and
a plurality capacitors formed over the first semiconductor substrate;
a second chip comprising:
a second semiconductor substrate;
a plurality of reset transistors formed over the second semiconductor substrate;
a plurality of source followers formed over the second semiconductor substrate;
a plurality of row selectors formed over the second semiconductor substrate; and
a plurality of input/output transistors formed over the second semiconductor substrate; and
a third chip comprising:
a third semiconductor substrate; and
a plurality of logic transistors formed over the third semiconductor substrate;
wherein the first to third chips are vertically bonded to one another.

12. The semiconductor device of claim 11, wherein the plurality of reset transistors, the plurality of source followers, the plurality of row selectors, and the plurality of input/output transistors operate under a first supply voltage, and the plurality of logic transistors operate under a second supply voltage, and wherein the first supply voltage is substantially higher than the second supply voltage.

13. The semiconductor device of claim 12, wherein the first supply voltage is greater than about 2 volts, and the second supply voltage is less than 2 volts.

14. The semiconductor device of claim 11, wherein the plurality of reset transistors, the plurality of source followers, the plurality of row selectors, and the plurality of input/output transistors are formed with a first dimension, and the plurality of logic transistors are formed with a second dimension, and wherein the first dimension is substantially greater than the second dimension.

15. The semiconductor device of claim 11, wherein the first chip is bonded to the second chip, with a front surface of the first semiconductor substrate facing a front surface of the second semiconductor substrate, and wherein the second chip is bonded to the third chip through one or more through substrate via (TSV) structures.

16. The semiconductor device of claim 11, wherein the first chip is bonded to the second chip through one or more through substrate via (TSV) structures, with a front surface of the first semiconductor substrate facing a back surface of the second semiconductor substrate, and wherein the second chip is bonded to the third chip through one or more metal pads.

17. The semiconductor device of claim 11, wherein the plurality of reset transistors, the plurality of source followers, and the plurality of row selectors are formed as an array, with the plurality of input/output transistors disposed around the array.

18. The semiconductor device of claim 11, wherein the plurality of input/output transistors collectively function as one or more input/output circuits each selected from the group consisting of: an electrostatic discharge (ESD) protection circuit, a column decoder, a row decoder, a level shift circuit, and combinations thereof.

19. A method, comprising:
forming a first chip including a plurality of photo-sensitive devices disposed over a first semiconductor substrate;
forming a second chip including: (i) a plurality of reset transistors disposed over a second semiconductor substrate; (ii) a plurality of source followers disposed over the second semiconductor substrate; (iii) a plurality of row selectors disposed over the second semiconductor substrate; and (iv) a plurality of input/output transistors disposed over the second semiconductor substrate;
bonding the second chip to the first chip;
forming a third chip including a plurality of logic transistors disposed over a third semiconductor substrate; and
bonding the third chip to the second chip.

20. The method of claim 19, wherein, on the second semiconductor substrate, the plurality of reset transistors, the plurality of source followers, and the plurality of row selectors are formed as an array, with the plurality of input/output transistors disposed around the array.
